(19) United States
(12) Patent Application Publication
(10) Pub. No.: US 2024/0218498 A1
(43) Pub. Date: Jul. 4, 2024

(54) Methods and Apparatus for Processing a Substrate

(71) Applicant: Applied Materials, Inc., Santa Clara, CA (US)

(72) Inventors: Goichi YOSHIDOME, Albany, CA (US); Xiangjin XIE, Fremont, CA (US)

(21) Appl. No.: 18/091,552

(22) Filed: Dec. 30, 2022

(51) Int. Cl. C23C 14/35; C23C 14/34; C23C 14/54

(52) U.S. Cl. CPC C23C 14/35; C23C 14/345; C23C 14/54

(57) ABSTRACT

Methods and apparatus for processing a substrate are provided. In some embodiments, a method for processing a substrate includes: energizing a target disposed at a distance from a plurality of magnets disposed within a processing volume of a processing chamber, and moving the plurality of magnets either away from or closer to the target at a predetermined distance based on an inverse target voltage curve that is determined using a third order polynomial.

### FIELD

Embodiments of the present disclosure generally relate to methods and apparatus for processing a substrate, and more particularly, to methods and apparatus for physical vapor deposition.

### BACKGROUND

The inventors have observed that target voltage drift as a function of target life (e.g., target erosion) in a physical vapor deposition (PVD) chamber can adversely affect a number of process parameters, such as deposition rate or properties of a deposited film on a substrate. The inventors have further observed that known compensation methods, for example, to maintain a constant deposition rate cannot suitably be used because they depend highly on target quality and performance consistency. The inventors believe that conventional compensation methods are not suitable for controlling the deposition rate. Moreover, attempts to control the deposition rate may not be suitable to control the other parameters impacted by target voltage drift.

Thus, the inventors have provided improved methods of controlling target voltage in a PVD process.

### SUMMARY

Methods and apparatus for processing a substrate are provided herein. In some embodiments, a method for processing a substrate includes: energizing a target disposed at a distance from a plurality of magnets disposed within a processing volume of a processing chamber; and moving the plurality of magnets either away from or closer to the target at a predetermined distance based on an inverse target voltage curve that is determined using a third order polynomial.

In some embodiments, a physical vapor deposition (PVD) processing chamber includes: a target disposed within a processing volume of a processing chamber; a plurality of magnets configured to produce a magnetic field within the plasma processing chamber; a power source configured to supply power to the processing chamber during operation; and a controller. The controller is configured to: energize the target during operation; and move the plurality of magnets either away from or closer to the target at a predetermined distance based on an inverse target voltage curve that is determined using a third order polynomial.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic, cross-sectional view of a processing chamber in accordance with at least some embodiments of the present disclosure.

FIG. 2 is a flowchart of a method of processing a substrate in accordance with at least some embodiments of the present disclosure.

FIG. 3 is a graph of target voltage and magnet spacing vs. target life in kilowatt hours (kWh) in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a methods and apparatus for processing a substrate are provided herein. For example, methods and apparatus described herein are configured to maintain a substantially constant target voltage during processing. For example, a method can include energizing a target disposed at a first distance from a plurality of magnets disposed within a processing volume of a processing chamber. During processing, the method can comprise moving the plurality of magnets either away from or closer to the target at a predetermined distance based on a predetermined magnetic lift compensation factor that is determined using two or more third order polynomials. Unlike the above-described known compensation methods, which rely heavily on target quality and/or target performance consistency, the methods and apparatus described herein maintain a substantially constant target voltage without having to alter a recipe time and/or make power adjustments to the target. Moreover, the methods and apparatus described herein can advantageously increase operable target life expectancy from about 1200 kilowatt hours to about 2000 kilowatt hours.

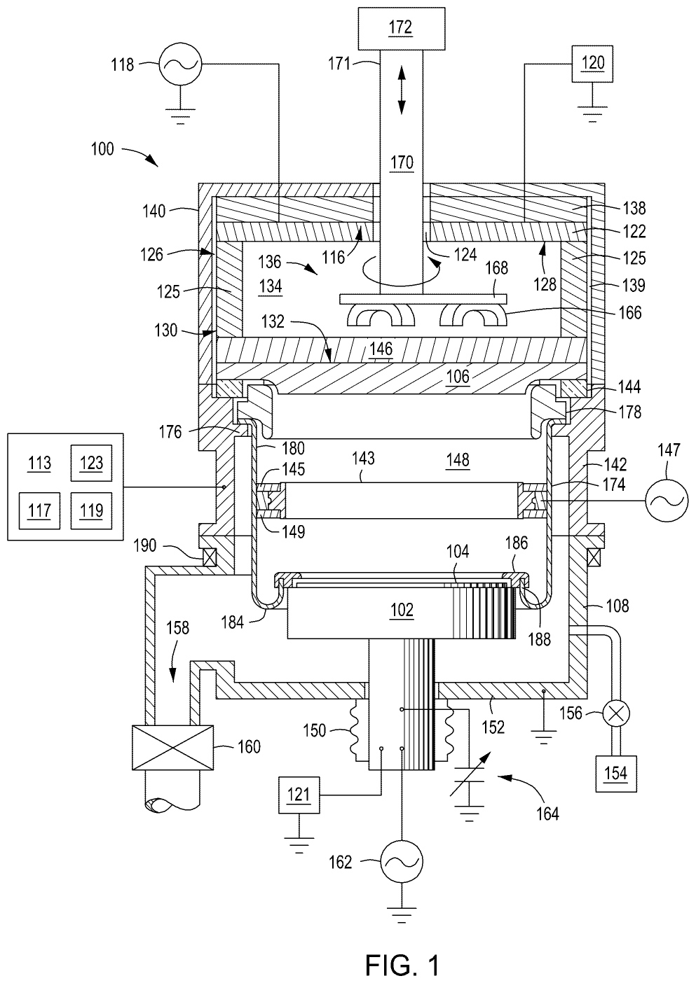

FIG. 1 depicts a schematic, cross-sectional view of a PVD processing chamber (processing chamber 100) in accordance with some embodiments of the present disclosure. Examples of suitable PVD chambers are commercially available from Applied Materials, Inc., of Santa Clara, California. Other processing chambers from Applied Materials, Inc. or other manufactures may also benefit from the inventive apparatus disclosed herein.

The processing chamber 100 contains a substrate support 102 for receiving a substrate 104 thereon, and a sputtering source, such as a target 106. The substrate support 102 may be located within a wall 108 (e.g., a grounded enclosure), which may be a chamber wall (as shown) or a grounded shield.

The processing chamber 100 includes one or more feed structures for coupling RF and/or DC energy to the target 106. The target 106 can be coupled to an RF power source 118 and/or to a DC power source 120, which can be utilized, independently or together, to respectively provide RF and/or DC energy to the target 106. For example, the DC power source 120 may be utilized to apply a negative voltage, or bias, to the target 106. In some embodiments, a plurality of RF power sources may be provided (i.e., two or more) to provide RF energy in a plurality of frequencies.

In some embodiments, the RF power source 118 and/or the DC power source 120 can be coupled to a source distribution plate 122. The source distribution plate 122 includes a hole 124 disposed therethrough to facilitate passage of a rotation shaft 170 of a rotatable magnetron assembly 136 as discussed in more detail below. The source distribution plate 122 may be fabricated from suitable conductive materials to conduct the RF and DC energy from the RF power source 118 and/or the DC power source 120. The source distribution plate 122 may be coupled to the target 106 via a conductive member 125. The conductive member 125 may be a tubular member having a first end 126 coupled to a target-facing surface 128 of the source distribution plate 122 proximate the peripheral edge of the source distribution plate 122. The conductive member 125 further includes a second end 130 coupled to a source distribution plate-facing surface 132 of the target 106 (or to the backing plate 146 of the target 106) proximate the peripheral edge of the target 106.

A ground shield 140 is shown covering at least some portions of the processing chamber 100 above the target 106 in FIG. 1. In some embodiments, the ground shield 140 could be extended below the target 106 to enclose the substrate support 102 as well. The ground shield 140 may be provided to cover the outside surfaces of a lid of the processing chamber 100. The ground shield 140 may be coupled to ground, for example, via a ground connection of the processing chamber 100 body. The ground shield 140 has a central opening to allow the rotation shaft 170 to pass through the ground shield 140. The ground shield 140 includes additional openings to route the feed structures therethrough (e.g., for RF and/or DC power) without electrically contacting the ground shield 140. The ground shield 140 may comprise any suitable conductive material, such as aluminum, copper, or the like.

An insulative gap 139 is provided between the ground shield 140 and the outer surfaces of the source distribution plate 122, the conductive member 125, and the target 106 (and/or backing plate 146) to prevent the RF and DC energy from being routed directly to ground. The insulative gap 139 may be filled with air or some other suitable dielectric material, such as a ceramic, a plastic, or the like.

An isolator plate 138 may be disposed between the source distribution plate 122 and the ground shield 140 to prevent the RF and DC energy from being routed directly to ground. The isolator plate 138 has a central opening to allow the rotation shaft 170 to pass therethrough. The isolator plate 138 includes additional openings to route the feed structures therethrough (e.g., for RF and/or DC power). The isolator plate 138 may comprise a suitable dielectric material, such as a ceramic, a plastic, or the like. Alternatively, an air gap may be provided in place of the isolator plate 138. In embodiments where an air gap is provided in place of the isolator plate, the ground shield 140 may be structurally sound enough to support any components resting upon the ground shield 140.

A cavity 134 may be defined by the inner-facing walls of the conductive member 125, the target-facing surface 128 of the source distribution plate 122 and the source distribution plate-facing surface 132 of the target 106. The cavity 134 can be utilized to at least partially house one or more portions of the rotatable magnetron assembly 136, as illustrated in FIG. 1. In some embodiments, the cavity may be at least partially filled with a cooling fluid, such as water (H₂O) or the like.

The target 106 may be supported on an adapter 142 (e.g., a grounded conductive aluminum adapter) through a dielectric isolator 144. The target 106 comprises a material to be deposited on the substrate 104 during sputtering, such a metal (or metal oxide) such as copper, tantalum, titanium, and the like. For example, in at least some embodiments the target 106 can be made from tantalum.

The backing plate 146 may be coupled to the source distribution plate-facing surface 132 of the target 106. The backing plate 146 may comprise a conductive material, such as copper-zinc, copper-chrome, or the same material as the target, such that RF and DC power can be coupled to the target 106 via the backing plate 146. Alternatively, the backing plate 146 may be non-conductive and may include conductive elements (not shown) such as electrical feedthroughs or the like for coupling the source distribution plate-facing surface 132 of the target 106 to the second end 130 of the conductive member 125. The backing plate 146 may be included for example, to improve structural stability of the target 106.

A rotatable magnetron assembly 136 may be positioned proximate a back surface (e.g., source distribution plate-facing surface 132) of the target 106. The rotatable magnetron assembly 136 includes a plurality of magnets 166 supported by a base plate 168. The base plate 168 connects to a rotation shaft 170 coincident with the central axis of the processing chamber 100, the target 106, and the substrate 104. The plurality of magnets 166 can be configured in a fixed position relative to the rotation shaft 170 or can have one or more adjustable positions relative to the rotation shaft 170. For example, in some embodiments, a two-position magnetron can be provided having an inner position for the plurality of magnets 166 (e.g., radially inner with respect to the rotation shaft 170) and an outer position for the plurality of magnets 166 (e.g., radially outer with respect to the rotation shaft 170).

A motion controller 172 can be coupled to the upper end of the rotation shaft 170 to drive rotation of the magnetron assembly 136. The motion controller 172, or a different motion controller, can be used to control the relative position of the plurality of magnets 166 of the rotatable magnetron assembly 136 with respect to the target 106 (e.g., to control the distance between the plurality of magnets 166 and the target 106). The motion controller can include one or more of a motor, a rotational actuator, a linear actuator, or the like. The plurality of magnets 166 produce a magnetic field within the processing chamber 100, generally parallel and close to the surface of the target 106 to trap electrons and increase the local plasma density, which in turn increases the sputtering rate. The plurality of magnets 166 produce an electromagnetic field around the top of the processing chamber 100, and plurality of magnets 166 are rotated to rotate the electromagnetic field which influences the plasma density of the process to sputter the target 106 more uniformly. For example, the rotation shaft 170 may make about 0 to about 150 rotations per minute.

In some embodiments, the motion controller 172 is configured to control rotation of the magnetron assembly 136, and a separate lift mechanism 171 is coupled to the rotation shaft 170 and configured to selectively raise or lower (e.g., control the distance of) the plurality of magnets 166 of the magnetron assembly 136 with respect to the back of the target 106. One such lift mechanism is disclosed in commonly owned U.S. Pat. No. 7,674,360, entitled “Mechanism for Varying The Spacing Between Sputter Magnetron And Target.”

In some embodiments, a magnet 190 may be disposed about the processing chamber 100 for selectively providing a magnetic field between the substrate support 102 and the target 106. For example, as shown in FIG. 1, the magnet 190 may be disposed about the outside of the wall 108 in a region just above the substrate support 102 when in processing position. In some embodiments, the magnet 190 may be disposed additionally or alternatively in other locations, such as adjacent the adapter 142. The magnet 190 may be an electromagnet and may be coupled to a power source (not shown) for controlling the magnitude of the magnetic field generated by the electromagnet.

The substrate support 102 has a material-receiving surface facing the principal surface of the target 106 and supports the substrate 104 to be sputter coated in planar position opposite to the principal surface of the target 106. The substrate support 102 may support the substrate 104 in a central region 148 of the processing chamber 100. The central region 148 is defined as the region above the substrate support 102 during processing (for example, between the target 106 and the substrate support 102 when in a processing position).

In some embodiments, the substrate support 102 may be vertically movable through a bellows 150 connected to a bottom chamber wall 152 to allow the substrate 104 to be transferred onto the substrate support 102 through a load lock valve (not shown) in the lower portion of the processing chamber 100 and thereafter raised to a deposition, or processing position.

One or more processing gases may be supplied from a gas source 154 through a mass flow controller 156 into the lower part of the processing chamber 100. An exhaust port 158 may be provided and coupled to a pump (not shown) via a valve 160 for exhausting the interior of the processing chamber 100 and facilitating maintaining a desired pressure inside the processing chamber 100.

An RF bias power source 162 may be coupled (e.g., through a matching circuit) to the substrate support 102 to induce a negative DC bias on the substrate 104. In addition, in some embodiments, a negative DC self-bias may form on the substrate 104 during processing. For example, RF power supplied by the RF bias power source 162 may range in frequency from about 2 MHz to about 60 MHz, for example, non-limiting frequencies such as 2 MHZ, 13.56 MHz, or 60 MHz can be used. In other applications, the substrate support 102 may be grounded or left electrically floating. In some embodiments, a capacitance tuner 164 may be coupled to the substrate support pedestal for adjusting voltage on the substrate 104 for applications where RF power is coupled to the target and RF bias power is not desired.

In some embodiments, the processing chamber 100 may further include a grounded bottom shield 174 connected to a ledge 176 of the adapter 142. A dark space shield 178 may be supported on the bottom shield 174 and may be fastened to the bottom shield 174 by screws or other suitable manner. The metallic threaded connection between the bottom shield 174 and the dark space shield 178 allows the bottom shield 174 and the dark space shield 178 to be grounded to the adapter 142. The adapter 142 in turn is sealed and grounded to the wall 108. Both the bottom shield 174 and the dark space shield 178 are typically formed from hard, non-magnetic metals, such as stainless steel or aluminum.

The bottom shield 174 extends downwardly and may include a generally tubular portion 180 having a generally constant diameter. The bottom shield 174 extends along the walls of the adapter 142 and the wall 108 downwardly to below a top surface of the substrate support 102 and returns upwardly until reaching a top surface of the substrate support 102 (e.g., forming a u-shaped portion 184 at the bottom). A cover ring 186 rests on the top of the upwardly extending inner portion 188 of the bottom shield 174 when the substrate support 102 is in a lower, loading position but rests on the outer periphery of the substrate support 102 when in an upper, deposition position to protect the substrate support 102 from sputter deposition. An additional deposition ring (not shown) may be used to shield the periphery of the substrate 104 from deposition.

In some embodiments, the processing chamber 100 may include an inductive coil 143 (e.g., for inductively coupled plasma process). The inductive coil 143 may have one or more turns. The inductive coil 143 may be just inside the bottom shield 174 and positioned above the substrate support 102. The inductive coil 143 may be positioned nearer to the substrate support 102 than the target 106. The inductive coil 143 may be formed from a material similar in composition to the target 106, such as, for example, tantalum or niobium, to act as a secondary sputtering target. The inductive coil 143 is supported from the bottom shield 174 by a plurality of coil spacers 145. The coil spacers 145 may electrically isolate the inductive coil 143 from the bottom shield 174 and other chamber components.

The inductive coil 143 may be coupled to a power source 147. The power source 147 may have electrical leads which penetrate the wall 108, the bottom shield 174, and the coil spacers 145. The electrical leads connect to a tab 149 on the inductive coil 143 for providing power to the inductive coil 143. The tab 149 may have a plurality of insulated electrical connections for providing power to the inductive coil 143. Additionally, the tab 149 may be configured to interface with the coil spacers 145 and support the inductive coil 143. The power source 147, in an embodiment, applies current to the inductive coil 143 to induce an RF field within the processing chamber 100 and couple power to the plasma for increasing the plasma density, e.g., concentration of reactive ions. In some embodiments, the inductive coil 143 is operated at an RF power frequency less than the RF power frequency of the RF power source 118. In one embodiment, the RF power frequency supplied to the inductive coil 143 is about 2 MHz. In other embodiments the RF power frequency may operate in a range of about 1.8 MHz to about 2.2 MHz. In other embodiments, the RF power frequency may range from about 0.1 MHz to 99 MHz. In some embodiments, the inductive coil 143 is made of a material, such as a metal material, that can be sputtered onto a substrate. The power source 147 may then also apply DC power to the inductive coil 143 to enable sputtering of the inductive coil 143 while coupling RF power to the plasma.

The processing chamber 100 includes a system controller 113 to control the operation of the processing chamber 100 during processing. The system controller 113 comprises a central processing unit (CPU) 117, a memory 119 (e.g., non-transitory computer readable storage medium), and support circuits 123 for the CPU 117 and facilitates control of the components of the processing chamber 100. The system controller 113 may be one of any form of general-purpose computer processor that can be used in an industrial setting for controlling various chambers and sub-processors. The memory 119 stores software instructions (source or object code) that may be executed or invoked to control the operation of the processing chamber 100 in the manner described herein. When processing the substrate 104, the processing chamber 100 can use the RF power source 118, the DC power source 120, and/or the power source 147 for sputtering a metal such as, for example, tantalum or titanium or a derivative thereof, etc. For example, in some embodiments, the DC power source 120 operates to produce DC power to sputter a metallic target while the power source 147 operates as a DC source to sputter the inductive coil 143 and operates as an RF power source at a frequency less than the operating RF frequency of the RF bias power source 162 to increase the plasma density in the central region 148. In some embodiments the power source 147 operates at an RF power frequency of about 0.1 MHz to 99 MHz. In other embodiments the power source 147 operates at an RF power frequency of about 1.8 MHz to about 2.2 MHz.

In some embodiments, the target 106 and the inductive coil 143 are composed of the same material such as, for example, tantalum or titanium, etc. The dual sources aid in providing a stable plasma and enough energy to selectively etch, for example, one or more process gases (e.g., at least one of argon, nitrogen, or one or more other noble gases) while keeping a metal film intact or at least minimally etched. The RF bias power source 162 operates at an RF power frequency greater than the operating RF power frequency of the power source 147 to bias the substrate 104. In some embodiments the RF bias power source 162 operates at an RF power frequency of about 1 MHz to about 100 MHZ. In other embodiments, the RF bias power source 162 operates at an RF power frequency of about 13.56 MHz.

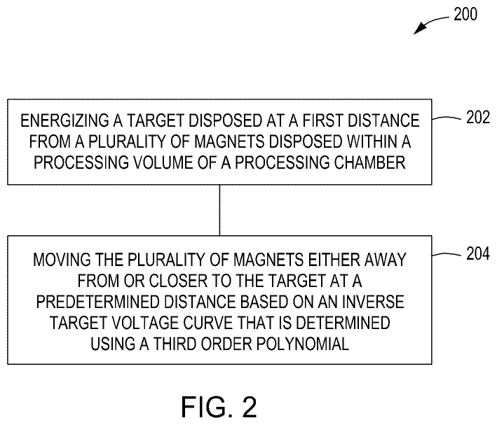

FIG. 2 is a flowchart of a method 200 (e.g., an open-loop feedback system) for processing a substrate in accordance with at least some embodiments of the present disclosure. For example, the method 200 uses a control algorithm to ensure that a substantially constant target voltage is maintained at the target. For illustrative purposes, the method 200 is described in terms of using a new target (e.g., at a beginning of a target's life)

In at least some embodiments, the method 200 can be used for high DC power deposition processes. During such processes, film properties, deposition rate, and the like, are dominated by target voltage. Accordingly, the method 200 can be used to maintain a substantially constant target voltage by adjusting a magnet (e.g., the plurality of magnets 166) distance relative to a target to maintain device yield, e.g., the same film property throughout target life. For example, with respect to PVD processes (e.g., a TaN PVD process), high target voltage provides high sputtering yield and high ion energy, which impacts deposition rate, adhesion, density, resistivity, and the like.

Likewise, the method 200 can be used for low DC power treatment deposition processes, e.g., dynamic treatment on ALD TaN, where inductive coil 143 voltage dominates film properties, such as for example, deposition rate and non-uniformity. The inventors have found that due to coupling between target and coil plasma, coil voltage can be modulated by target voltage. Accordingly, the method 200 can maintain a substantially constant target voltage by adjusting the magnet distance relative to the target, e.g., coil voltage can be adjusted and compensated throughout target and coil life.

For example, the inventors have found that a control algorithm that uses a high order polynomial (e.g., a nonlinear function) provides superior performance for following an erosion rate of a target. Such high order polynomials are configurable to compensate for relatively small erosion of a target and perform more consistently when compared to control algorithms that use linear functions. In at least some embodiments, the high order polynomial can be a second order polynomial or greater. For example, in at least some embodiments, the high order polynomial can be a third order polynomial in a form of Equation (1):

$$y = {{c}_{3}^{*} ( x - {x}_{0} )}^{3} + {{c}_{2}^{*} ( x - {x}_{0} )}^{2} + {c}_{1}^{*} ( x - {x}_{0} ) + {c}_{0} \qquad ( 1 )$$

wherein y=target to plurality of magnets spacing offset, x=target age in kWh, and x₀=starting target age in kWh (e.g., after burn-in), and cₒ=magnet lift position offset from an initial target spacing setpoint at target life 0 (e.g., 0 kWh). In the above example, the spacing, or distance, between the target and the plurality of magnets is measured between the front surface of the plurality of magnets and the facing surface of the target assembly (e.g., the top surface of the backing plate 146 shown in FIG. 1). However, other reference points may be used to define the distance between the plurality of magnets and the target assembly, and the distance can be adjusted accordingly. In some embodiments, the above equation can be used for a magnetron that rotates the plurality of magnets in a fixed radial position with respect to the axis of rotation. In some embodiments, the above equation can be used for a magnetron that rotates the plurality of magnets in at least two fixed radial positions with respect to the axis of rotation (e.g., at least an inner radial position and an outer radial position).

For example, when beginning a process with a new target, an initial distance between the plurality of magnets and the target can be set (e.g., an initial spacing setpoint) to provide a desired target voltage given the target material and process conditions to be performed. In some embodiments, for example, the initial spacing setpoint can be about 1.25 mm, although other distances can be used depending upon the process chamber configuration. After burn-in of the new target, the above equation can be used to determine the spacing of the plurality of magnets from the target (e.g., y can be calculated at target life x=x₀) by adding the calculated y value to the initial spacing setpoint. As substrates are processed over time, the above equation can be used to determine the spacing of the plurality of magnets from the target as the target life advances (e.g., by calculation of y at the target life and adding the calculated y value to the initial spacing setpoint).

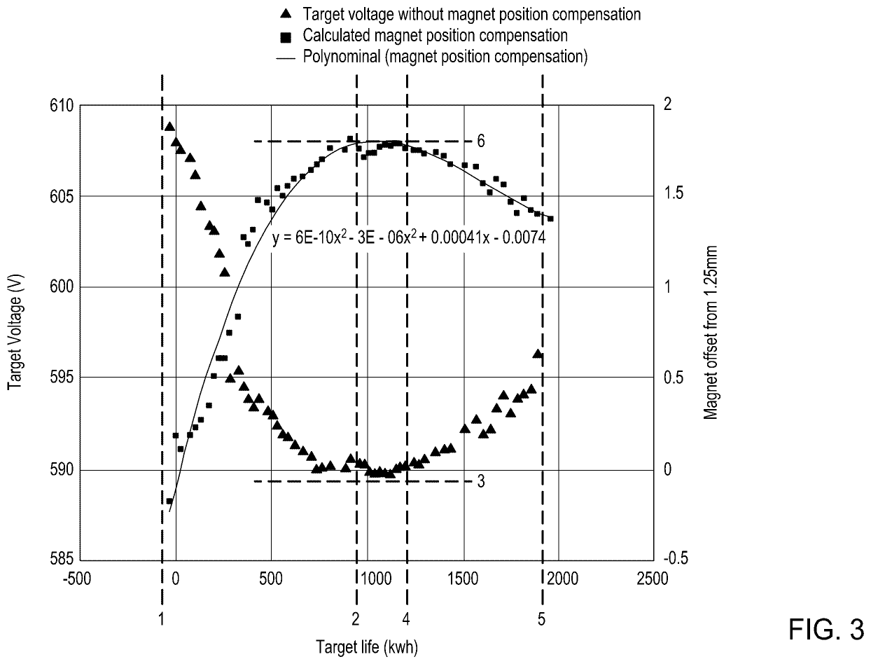

In at least some embodiments, the third order polynomial uses coefficients (e.g., constants) that are specific for a corresponding target. That is, the constant coefficients for a particular target are configured to provide an inverse for a corresponding voltage curve. Once the coefficients are calculated for a specific target, the control algorithm uses the coefficients to determine a magnetic lift compensation factor for that specific target. For example, the coefficients c₁-c₃ can be configured to represent an erosion rate of a corresponding target. For example, through empirical data, the inventors have developed target voltage curves (e.g., target voltage vs. target life in kilowatt hours (kWh), as shown in FIG. 3) that are specific for a corresponding target (e.g., tantalum, titanium, etc.) and that are indicative of prior demonstrated performance of the corresponding target. For example, the inventors have found that at a beginning of target life, target voltage will begin to decrease (triangular data from point 1 to point 2 on the graph of FIG. 3) during substrate processing, and based on a particular target, will hit a bottom inflection point (triangular data point 3 on the graph of FIG. 3) with continued substrate processing, and will then begin to increase (triangular data from point 4 to point 5 on the graph of FIG. 3) as substrate processing continues. For example, for at least some tantalum targets, at a beginning of a target life (e.g., 0 kWh), a target voltage provided at the target can be about 610 volts. As the target is used, the target voltage at the target will begin to decrease (e.g., to about 500 volts) and hit the bottom inflection at about 1000 kWh. Thereafter, the target voltage at the target will begin to increase to about 600 volts at about 1800 kWh. The above process can be used to determine the coefficients c₁-c₃ for other processes, such as for example, processes using different target materials, different chamber configurations, or the like.

At 202, the method includes energizing a target disposed at a distance from a plurality of magnets disposed within a processing volume of a processing chamber. For example, a target (e.g., the target 106) is energized using, for example, DC energy provided by a respective DC power source (e.g., the DC power source 120). The target can be disposed at a first distance from a plurality of magnets (e.g., the plurality of magnets 166) disposed within a processing volume of a processing chamber (e.g., the processing chamber 100).

Next, at 204, the method includes, either moving the plurality of magnets away from or closer to the target based on a predetermined inverse voltage curve trajectory (e.g., an inverse of a target voltage curve) that is determined using, for example, the above described third order polynomial. For example, the inventors have developed an open loop control algorithm, e.g., magnet position as a function of the kWh for a corresponding target, that is configured to determine a target voltage curve using an inverse voltage curve trajectory that is determined based on the third order polynomial. For each corresponding target, the open loop control algorithm is configured to develop a linear voltage response over the corresponding target life (e.g., kWh), which will provide repeatability from target to target. For example, the methods and apparatus described herein enable a user to achieve desired processing results, by adjusting a magnet-to-target spacing as function of kilowatt hours to maintain a substantially constant voltage (e.g., to within about 1% to about 3% and in some embodiments, from about 0.75% to about 1.5% of a predetermined voltage) over the course of the target life. For different target materials, process chamber configurations, and/or processing conditions, the initial third order polynomial can be calculated empirically through, for example, test runs through one or more targets.

Thus, since the method 200 uses a new target (e.g., the target voltage will decrease as the target erodes), the controller moves the plurality of magnets a predetermined distance away from (or toward) the target based on the previously determined inverse voltage curve trajectory (rectangular data from point 1 to point 2 on the graph of FIG. 3). The controller continues to move the plurality of magnets to a predetermined distance away from the target until the target voltage reaches the plateau (top inflection point rectangular data point 6 on the graph of FIG. 3) on the voltage curve for that target (e.g., about 1000 kWh). Thereafter, with continued substrate processing, the inverse voltage curve begins to decrease (rectangular data from point 4 to point 5 on the graph of FIG. 3) as substrate processing continues, and the controller begins to move the plurality of magnets a predetermined distance toward the target until the inverse voltage curve trajectory (rectangular data on the graph of FIG. 3) and the voltage target curve (e.g., triangular graph of FIG. 3) converge (not shown), at which time the target can be replaced. In at least some embodiments, e.g., using different targets, the trajectory curves and/or the high order polynomial can be adjusted to accommodate different targets. The calculation and adjustment of the magnet to target spacing can be performed at any time, such as continuously, after each substrate is processed, or after a set amount of time or a set number of substrates have been processed.

As noted above, moving the plurality of magnets to maintain a substantially constant target voltage can have multiple advantages including: 1) control of ion energy and hence sputtering yield, which directly impacts processing parameters such as deposition rate, adhesion, density, and resistivity; and 2) control of the coil voltage to provide high film deposition rate and uniformity.

During the operable life of a target, the target can advantageously be maintained at a substantially constant voltage (e.g., to within about 1% to about 3% and in some embodiments, from about 0.75% to about 1.5% of a nominal target voltage) by raising or lowering the plurality of magnets. The nominal target voltage can be a predetermined target voltage, an average target voltage, a resultant target voltage established by processing a substrate using a particular process recipe, or the like.

Moreover, one or more additional processing chamber parameters can also be adjusted/modified in addition to moving the magnets. For example, one or more of adjusting a power supplied to the target, a gas flow rate of a process gas, or a radial position of the plurality of magnets can also be performed prior to or after 208.

While the foregoing is directed to embodiments of the present disclosure, other and further embodiments of the disclosure may be devised without departing from the basic scope thereof.

1. A method for processing a substrate, comprising:
energizing a target disposed at a distance from a plurality of magnets disposed within a processing volume of a processing chamber; and
moving the plurality of magnets either away from or closer to the target at a predetermined distance based on an inverse target voltage curve that is determined using a third order polynomial.

2. The method of claim 1, wherein the target is at least one of tantalum or titanium.

3. The method of claim 1, wherein the third order polynomial uses coefficients that are specific for a corresponding target.

4. The method of claim 3, wherein the coefficients that are specific for the corresponding target are based upon an erosion rate of the corresponding target.

5. The method of claim 1, wherein the third order polynomial is in a form of:
$$y = {{c}_{3}^{*} ( x - {x}_{0} )}^{3} + {{c}_{2}^{*} ( x - {x}_{0} )}^{2} + {c}_{1}^{*} ( x - {x}_{0} ) + {c}_{0}$$
wherein y=target to plurality of magnets spacing offset, x=target kWh, and x₀=starting target kWh.

6. The method of claim 1, wherein a voltage of the target is maintained to about 1 percent to about 3 percent of a nominal target voltage.

7. The method of claim 1, further comprising adjusting at least one of power supplied to the target, a gas flow rate of a process gas, or a radial position of the plurality of magnets.

8. A non-transitory computer readable storage medium having stored thereon instructions that when executed by a processor perform a method for processing a substrate, comprising:
energizing a target disposed at a distance from a plurality of magnets disposed within a processing volume of a processing chamber; and
moving the plurality of magnets either away from or closer to the target at a predetermined distance based on an inverse target voltage curve that is determined using a third order polynomial.

9. The non-transitory computer readable storage medium of claim 8, wherein the target is at least one of tantalum or titanium.

10. The non-transitory computer readable storage medium of claim 8, wherein the third order polynomial uses coefficients that are specific for a corresponding target.

11. The non-transitory computer readable storage medium of claim 10, wherein the coefficients that are specific for the corresponding target are based upon an erosion rate of the corresponding target.

12. The non-transitory computer readable storage medium of claim 8, wherein the third order polynomial is in a form of:
$$y = {{c}_{3}^{*} ( x - {x}_{0} )}^{3} + {{c}_{2}^{*} ( x - {x}_{0} )}^{2} + {c}_{1}^{*} ( x - {x}_{0} ) + {c}_{0}$$
wherein y=target to plurality of magnets spacing offset, x=target kWh, and xₒ=starting target kWh.

13. The non-transitory computer readable storage medium of claim 8, wherein a voltage of the target is maintained to about 1 percent to about 3 percent of a nominal target voltage.

14. The non-transitory computer readable storage medium of claim 8, further comprising adjusting at least one of power supplied to the target, a gas flow rate of a process gas, or a radial position of the plurality of magnets.

15. A physical vapor deposition (PVD) processing chamber, comprising:
a target disposed within a processing volume of a processing chamber;
a plurality of magnets configured to produce a magnetic field within the processing chamber;
a power source configured to supply power to the processing chamber during operation; and
a controller configured to:
energize the target during operation; and
move the plurality of magnets either away from or closer to the target at a predetermined distance based on an inverse target voltage curve that is determined using a third order polynomial.

16. The PVD processing chamber of claim 15, wherein the target is at least one of tantalum or titanium.

17. The PVD processing chamber of claim 15, wherein the third order polynomial uses coefficients that are specific for a corresponding target.

18. The PVD processing chamber of claim 17, wherein the coefficients that are specific for the corresponding target are based upon an erosion rate of the corresponding target.

19. The PVD processing chamber of claim 15, wherein the third order polynomial is in a form of:
$$y = {{c}_{3}^{*} ( x - {x}_{0} )}^{3} + {{c}_{2}^{*} ( x - {x}_{0} )}^{2} + {c}_{1}^{*} ( x - {x}_{0} ) + {c}_{0}$$
wherein y=target to plurality of magnets spacing offset, x=target kWh, and x₀=starting target kWh.

20. The PVD processing chamber of claim 15, wherein the controller is further configured to maintain a voltage of the target at about 1 percent to about 3 percent of a nominal target voltage during use.
